(19) United States
(12) Patent Application Publication
(10) Pub. No.: US 2005/0062151 A1
(43) Pub. Date: Mar. 24, 2005

(54) Semiconductor integrated circuit and electronic apparatus having the same

(75) Inventor: Atsuo Nagao, Ukyo-ku (JP)

Correspondence Address: HOGAN & HARTSON L.L.P., 500 S. GRAND AVENUE, SUITE 1900, LOS ANGELES, CA, 90071-2611, US

(73) Assignee: ROHM CO., LTD

(21) Appl. No.: 10/945,569

(22) Filed: Sep. 20, 2004

(30) Foreign Application Priority Data
Sep. 22, 2003 (JP) 2003-329452

(51) Int. Cl. H01L 23/48

(52) U.S. Cl. 257/734

(57) ABSTRACT

An IC has a multiplicity of electrodes or terminals arranged in a grid array configuration. The IC is provided with a multiplicity of pads in a similar grid array configuration. The pads other than the outermost pads of the array are used as signal pads. The outermost pads are used as reinforcing pads, which are connected to the signal pads adjacent the reinforcing pads. Bumps provided on the reinforcing pads and on the signal pads connected to the reinforcing pads are connected to associated bumps en bloc on an assembly board, thereby allowing the IC to be bonded to the assembly board with sufficient mechanical strength.

### FIELD OF THE INVENTION

This invention relates to a semiconductor integrated circuit having a multiplicity of terminals arranged in a grid array configuration, and to an electronic apparatus equipped with such IC.

### BACKGROUND OF THE INVENTION

Semiconductor integrated circuits (hereinafter referred to as ICs) are mostly packaged to contain an integrated circuit chip. Such IC has electrodes or terminals arranged in, for example, a so-called ball grid array (BGA) structure, in which electrodes are ball-shaped solder bumps arranged in a grid array configuration on one primary side of the IC. ICs having a BGA structure (referred to as BGA type ICs) can be easily equipped with many terminals while keeping substantially the same dimensions as the dimensions of the chip. For this reason, BGA type ICs are called chip-size packages (CSP). BGA type ICs have a further advantage in that an assembly board such as a printed circuit board for assembling thereon the IC only requires substantially the same space as the IC chip. Such assembly boards are used in different electronic apparatuses such as electronic cards, cellular phones, and personal computers.

A BGA type IC is bonded onto the assembly board of an electronic apparatus together with other electronic components of the apparatus such as other semiconductor devices, capacitors, and resistors for mechanical and electric connection with high density.

The BGA type IC is bonded onto the assembly board by a reflow processing. The assembly board and/or the IC suffer from heating during the reflow processing, and can be deformed by the heat. They also suffer from cyclic heating, and hence resultant distortions due to a difference in thermal expansion coefficients between them, while they are in use. Thus, on account of such thermal deformations in the manufacturing process and/or distortions during its use, stress can be developed in the BGA electrodes bonded to the assembly board, thereby breaking the bondage between the BGA electrodes and the assembly board.

To prevent such break of the BGA electrodes from the assembly board as mentioned above, reinforcing bumps may be provided at the four corners of a rectangular package to mechanically reinforce the package, as disclosed in Japanese Patent Early Publication No. 2001-68594.

In this prior art reinforcing technique, to enhance the mechanical strength of bump-electrode bonding, a single large reinforcing bump is provided at each of the four corners or multiple reinforcing bumps are collectively provided at the four corners. Although use of such reinforcing bumps can improve the mechanical strength, a BGA type IC has a complicated configuration, and hence manufacture of the BGA type IC can entail a new problem to deal with the complexity, since signal bumps and reinforcing bumps have different shapes and different arrangements.

### SUMMARY OF THE INVENTION

It is therefore an object of the invention to provide a BGA type IC having a multiplicity of reinforcing bumps of substantially the same dimensions as the signal bumps arranged uniformly in the same grid array configuration as the signal bumps, thereby providing the IC with sufficient bonding strength to an assembling board.

It is another object of the invention to provide a reliable electronic apparatus equipped with the inventive IC.

### DISCLOSURE OF THE INVENTION

In accordance with one aspect of the invention, there is provided an IC having a multiplicity of pads of substantially the same size and arranged in a grid array configuration, and a multiplicity of bumps of substantially the same size and formed on the respective pads, wherein
the multiplicity of pads excluding the outermost ones of the array serve as signal pads to be connected to internal circuits of the IC;
the outermost pads serve as reinforcing pads to be connected to signal pads inside and adjacent the outermost pads by inter-pad lead wires; and
the bumps are provided one for each of the signal pads and reinforcing pads.

The grid array configuration may be generally rectangular. Three reinforcing pads located at each corner of the array (referred to as reinforcing corner pads) are connected to one signal pad inside the reinforcing corner pads (referred to as corner signal pad) by inter-pad lead wires, while each of the outermost reinforcing pads located on either side of the array but not at the corners (referred to reinforcing side pads) is connected to an associated one of the signal pads inside and adjacent the side (referred to as inner side-wise signal pads) by an inter-pad lead wire.

The inter-pad lead wires connecting the three reinforcing corner pads to the associated corner signal pad may have collectively a shape of X, while
the inter-pad lead wires connecting the reinforcing side pads to the inner side-wise signal pads may have a linear shape.

The inventive IC has a multiplicity of pads of substantially the same size and arranged in a generally rectangular grid array configuration, and a multiplicity of bumps of substantially the same size and respectively formed on the pads, wherein the multiplicity of pads excluding the outermost pads in a pair of opposing sides of the rectangular array serve as signal pads to be connected to internal circuits of the IC, while the outermost pads on the two opposing sides serve as reinforcing pads to be connected to the signal pads inside and adjacent the sides by linear inter-pad lead wires, and
the bumps are provided one for each of the signal pads and reinforcing pads.

In another aspect of the invention, there is provided an electronic apparatus equipped with:
an IC having a multiplicity of pads of substantially the same size and arranged in a grid array configuration, and a multiplicity of bumps of substantially the same size and respectively formed on the pads, wherein
   said multiplicity of pads excluding the outermost ones of the array serve as signal pads to be connected to internal circuits of the IC;
   the outermost pads serve as reinforcing pads to be connected to signal pads inside and adjacent the outermost pads by inter-pad lead wires; and
   the bumps are provided one for each of the signal pads and reinforcing pads, and
an assembly board having
   a multiplicity of circumferential electrodes each matching in size both at least one associated reinforcing pad and the signal pad connected to the reinforcing pad; and
   a multiplicity of central electrodes each matching in size an associated signal pad not connected to the reinforcing pad, wherein
each of the central electrodes is bonded to an associated one of the bumps, while each of the circumferential electrodes is bonded to a multiplicity of associated bumps en bloc.

The inventive IC for use in the electronic apparatus may be constructed such that:
the grid array configuration is generally rectangular;
three reinforcing pads located at each corner of the array (referred to as reinforcing corner pads) are connected to one signal pad inside and adjacent the reinforcing corner pads (referred to as corner signal pad) by inter-pad lead wires, while each of the outermost reinforcing pads located on either side of the array but not at the corners (referred to reinforcing side pads) is connected to an associated one of the inner side-wise signal pads adjacent the side by an inter-pad lead wire. The assembly board of the electronic apparatus may be provided with corner electrodes and side-wise electrodes, each corner electrode matching in size both three associated reinforcing corner pads at that corner and the corner signal pad, and each side-wise electrode matching in size both an associated reinforcing side pad and the associated signal pad connected to the reinforcing side pad, wherein:
   each of the central electrodes is individually bonded to an associated one of the bump, while each of the corner electrodes is bonded to four associated bumps en bloc, and each of the side-wise electrodes is bonded to two associated bumps en bloc.

In this IC, the inter-pad lead wires connecting the three reinforcing corner pads to the associate corner signal pad may have collectively a shape of X, while the inter-pad lead wires connecting the reinforcing side pads to the respective associated inner side-wise signal pads may have a linear shape.

The inventive electronic apparatus may comprise:
an IC having a multiplicity of pads of substantially the same size and arranged in a generally rectangular grid array configuration, and a multiplicity of bumps of substantially the same size and respectively formed on the pads, wherein
   pads other than the outermost pads in a pair of opposing sides of the rectangular array serve as signal pads to be connected to internal circuits of the IC, while the outermost pads in the two opposing sides serve as reinforcing pads to be connected to the signal pads inside and adjacent the sides by linear inter-pad lead wires, and
   the bumps are provided one for each of the signal pads and reinforcing pads, and
an assembly board having a multiplicity of circumferential electrodes each matching in size both at least one associated reinforcing pad and the signal pad connected to the reinforcing pad, and a multiplicity of central electrodes each matching in size an associated signal pad not connected to the reinforcing pad, wherein each of the central electrodes is bonded to an associated one of the bumps, while each of the circumferential electrodes is bonded to a multiplicity of associated bumps en bloc.

In the inventive electronic apparatus equipped with an IC as described above, at least one of the circumferential electrodes is omitted to provide a spacing for passing therethrough at least one lead-wire for a central electrode.

In accordance with the invention, BGA type ICs and PGA (pin grid array) type ICs can be bonded to an assembly board (or a product board for assembling electronic parts in manufacturing a product) with sufficient mechanical strength using uniformly distributed bumps (e.g. ball-shaped electrode and post shaped electrodes) having the same shape. As a result, bonding failure of bumps from the assembly board arising from distortion of the board due to thermal stress applied during its manufacture can be reduced.

Packaging of the inventive ICs is easy, since all the bumps are of the same shape and arranged uniformly in a grid array configuration.

Moreover, since reinforcing bumps and the signal bumps connected to the reinforcing bumps can be regarded as a unified bump, a large electrode (pad) can be formed for the unified bump, providing enhanced soldering of the bumps of the assembly board.

The invention provide a further advantage in that the quality of electrical connection of an IC can be easily tested using bumps formed on the reinforcing pads and the associated bumps provided on the signal pads inside and adjacent the reinforcing pads. Thus, if a bump is disconnected from its pad, disconnection can be found in the test.

### BRIEF DESCRIPTION OF THE DRAWINGS

FIG. 1 shows a pad pattern of an IC in accordance with a first embodiment of the invention.

FIG. 2 shows a bump pattern of the IC of FIG. 1 in accordance with the first embodiment of the invention.

FIG. 3 shows an electrode pattern of the IC of FIGS. 1 and 2 assembled on an assembly board.

FIG. 4 shows a section of the IC of FIG. 1 assembled on a assembly board,

FIG. 5 shows a pad pattern of an IC in accordance with a second embodiment of the invention.

FIG. 6 shows a bump pattern of the IC of FIG. 5 in accordance with the second embodiment of the invention.

FIG. 7 shows an electrode pattern of the IC of FIGS. 5 and 6.

### DETAILED DESCRIPTION OF THE PREFERRED EMBODIMENT

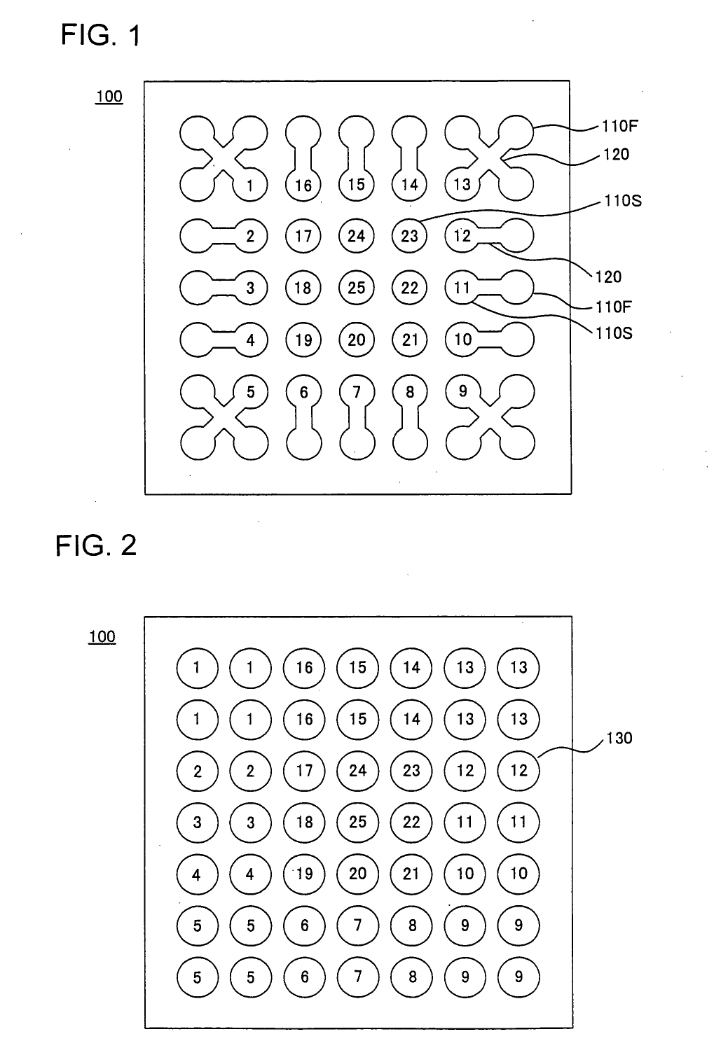

An inventive IC and an inventive electronic apparatus equipped with the IC will now be described in detail by way of example with reference to the accompanying drawings. FIGS. 1 through 4 show a first embodiment of the invention.

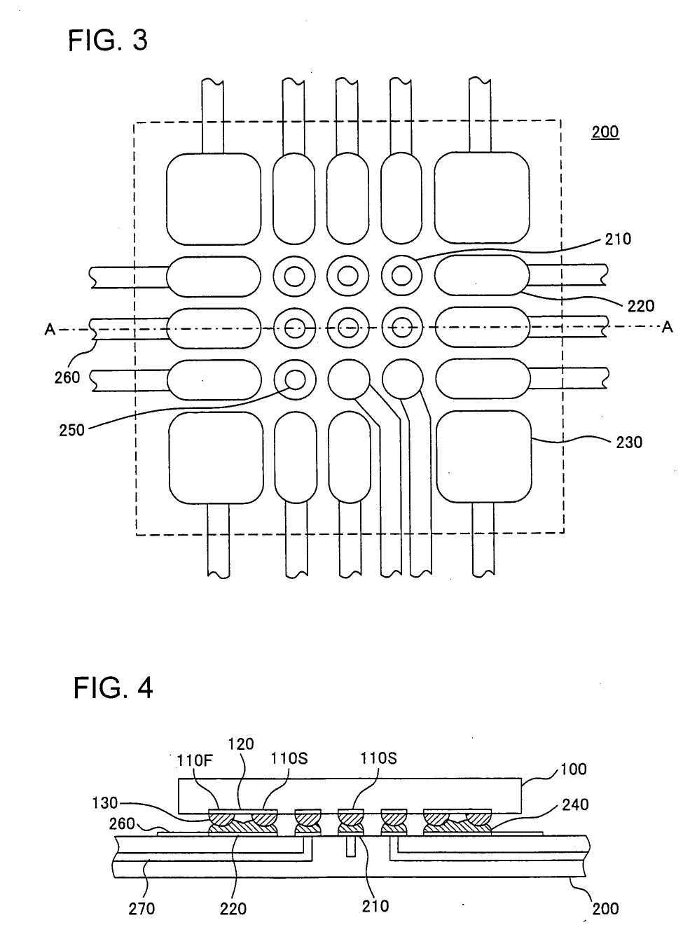

FIG. 1 shows a grid array pattern of pads arranged on the primary side of the IC. FIG. 2 shows a pattern of bumps formed on the respective pads. FIG. 3 shows a pattern of electrodes (pads) formed on the assembly board for assembling the IC of FIGS. 1 and 2. FIG. 4 shows a schematic sectional view of the IC assembled on the assembly board.

As shown in FIG. 1, an IC 100 has a multiplicity of pads 110 of substantially the same size arranged in a grid array configuration on a region of the primary side of the IC chip. The region is mostly rectangular in shape, but it can be square as shown in FIGS. 1 and 2. The number of pads 110 is not limited to the number shown in FIG. 1, but is rather arbitrary.

Of the multiplicity of pads 110 in the grid array, those other than the outermost ones serve as signal pads 110S for connection with internal circuits of the IC. These signal pads 110S are numbered 1 through 25, as shown in FIG. 1.

Of the multiplicity of pads 110, the outermost pads 110F serve as reinforcing pads. The reinforcing pads 110F are connected to the respective signal pads 110S arranged inside and adjacent the reinforcing pads 110F by inter-pad lead wires 120. Thus, the multiplicity of pads 110 are partly used as the signal pads 110S and partly as the reinforcing pads 110F.

Three reinforcing pads 110F at each of the four corners (referred to as reinforcing corner pads) are connected to one signal pad 110S inside the three reinforcing pads numbered 1, 5, 9, and 13 (referred to as corner signal pad) by inter-pad lead wires 120. There is provided at each corner a collectively X-shaped inter-pad lead wire 120.

The reinforcing pads 110F located on either side of the array but not at the corners (referred to as reinforcing side pads) are respectively connected to an associated signal pad 110S (referred to as inner side-wise signal pad) numbered 2-4, 6-8, 10-12 and 14-16 that is located inside and adjacent the side, by inter-pad lead wires 120. These inter-pad lead wires 120 associated with the side-wise pads have a linear shape.

Referring to FIG. 2, there is shown an arrangement of ball-shaped bumps (ball electrodes) 130 formed on the respective pads 110 of FIG. 1. These bumps 130 have substantially the same form, and are uniformly distributed in a grid array configuration similar to that of pads 110. Thus, the IC is said to have a ball grid array (BGA) structure. Alternatively, each of the electrodes may be a pin-shaped electrode. Then the IC is said to have a pin grid array (PGA) structure. These ball electrodes and pin electrodes are made of any ordinary electrode material including solder, gold, and alloys. As seen in FIG. 2, bumps are not formed on inter-pad lead wires 120 to suppress variation in the size of the bumps.

These bumps 130 are formed on the respective pads 110 irrespective of whether they are signal pads 110S or reinforcing pads 110F. The reinforcing pads 110F are respectively connected to corresponding signal pads 110S by inter-pad lead wires 120.

Thus, as shown in FIG. 2, the bumps 130 associated with the terminals are numbered 1 through 25 in association with the numbers of the corresponding signal pads 110S. On the other hand, the bumps 130 associated with the reinforcing pads 110F are numbered 1 through 16 in association with the numbers of the corresponding signal pads 110S that are connected to the reinforcing pads 110F.

In this way, the reinforcing pads 110F of the IC 100 are connected to the signal pads 110S by lead wires 120. It should be noted that when testing the IC 100, the electrical connection between the bumps 130 and the associated pads 110 can be easily tested by checking electrical connection between the bumps formed on the reinforcing pads 110F and the bumps formed on the associated signal pads 110S inside and adjacent the reinforcing pads 110F. If a bump 130 is disconnected from a corresponding pad 110, connection failure can be easily found in the IC test.

Referring to FIG. 3, there is shown a pattern (or array) of electrodes (or pads) formed on an assembly board 200 for assembling thereon the IC 100 of FIGS. 1 and 2. In the example shown in FIG. 3, the assembly board 200 has the same size as the IC 100 as indicated by a phantom line. In actuality, however, the assembly board 200 is much larger than the IC 100 so that the assembly board can assemble further components and other ICs.

As shown in FIG. 3, there are provided on the assembly board 200 central electrodes (pads) 210 located in the central region (i.e. region inside the circumference) of the array, side-wise electrodes (pads) 220 located on the sides of the array, and corner electrodes (pads) 230 located at the corner of the array and bonded to the bumps 130 of the IC 100.

Each of the central electrodes 210 is individually bonded to an associated one of the bumps 130 numbered 17 through 25 that are not connected to the reinforcing pads 110F. The central electrodes 210 are in general connected to other components and ICs using a multilevel interconnection technique.

Each of the side-wise electrodes 220 has an area that matches in size the associated reinforcing pad 110F lying on one side of the array and of the signal pad 110S connected to the reinforcing pad 110F. Each of the side-wise electrodes 220 is bonded to two bumps 130 en bloc by a bonding material, with one bump 130 located on one side-wise reinforcing pad 110F and another bump 130 located on the signal pad 110S connected to the reinforcing pad 110F.

Each of the corner electrodes 230 at one corner has an area that match in size the entirety of three neighboring reinforcing pads 110F at that corner and the signal pad 110S connected to the three reinforcing pads 110F. One corner electrode 230 at one corner is bonded to four corner bumps en bloc by a bonding material at that corner, the four bumps including three bumps 130 formed on the three corner reinforcing pads 110F and one bump 130 formed on the signal pad 110S connected to the three reinforcing pads 110F. The bonding material is arbitrary so long as it can electrically and mechanically couple the bumps 130 of the IC 200 to the electrodes 210, 220, and 230 of the assembly board 100 with sufficient strength. An example of bonding materials is a cream solder, which can be melted by heat to bond the bumps 130 to the pads.

In general, the side-wise electrodes 220 and the corner electrode 230 are connected to other components and ICs using lead wires 260 formed on the surface of the assembly board 200. These side-wise electrodes 220 and corner electrodes 230 can be connected by multilevel interconnections 270 (FIG. 4) formed inside the assembly board 200. The central electrodes 210 are preferably connected to other components and ICs using through-holes 250 and multilevel interconnections 270.

As seen from FIG. 3, one or more of the side-wise electrodes 220 (the electrode that corresponds to the signal pad 110S numbered 8 in the example shown) can be omitted to provide a wiring space for one or more of the central electrodes. In the example shown herein, two lead wires 260 extend outwardly from the central electrodes (associated with the signal pads 110S numbered 20 and 21) through such wiring space. In this way, one or more of the side-wise (or circumferential) electrodes 220 can be omitted as needed.

Referring now to FIG. 4, there is shown a cross section of the IC 100 assembled on the assembly board 200 in accordance with a first embodiment of the invention, the cross section taken along line A-A of FIG. 3.

It is shown in FIG. 4 that solder 240 is provided as a bonding material on the respective electrodes 210, 220, and 230 (not shown) of the assembly board 200. The IC 200 is mounted on the solder 240 formed on the respective pads such that the grid array of bumps 130 are correctly aligned with the respective central electrodes 210, side-wise electrodes 220, and corner electrodes 230. Then the assembly board 200 and IC 200 are heated for reflow-soldering of the bumps 130 by the solder 240, which causes the electrodes 210, 220, and 230 to be bonded to the bumps 130.

In accordance with the first embodiment of the invention, mechanically strong bonding of a BGA type and a PGA type IC 100 onto an assembly board 200 can be attained using uniformly distributed bumps 130 (e.g. ball-shaped electrodes, pin-shaped electrodes, mailbox-shaped electrodes) of the same size. Thus, if the assembly board 200 is thermally deformed during its manufacture, possible disconnection of the bumps 130 from the assembly board 200 can be prevented.

It will be appreciated that all the bumps 130 are uniformly distributed over the grid array, so that packaging of the IC can be easily carried out through an ordinary packaging process for BGA type and PGA type ICs.

The bump 130 formed on a reinforcing pad 110F and the bump 130 formed on the associated signal pad 110S connected to the reinforcing pad 110F can be regarded as a cluster of unified bumps (referred to as unified bumps). Each of the circumferential electrodes 220 and 230 is provided on the assembly board 200 in association with the unified bumps. Thus, each of the circumferential electrodes 220 and 230 has an enlarged area in accord with the multiplicity (two or four) of the unified bumps. Each large circumferential electrode (220 or 230) is soldered to the unified bumps over a wide area by a bonding material, thereby enhancing the strength of the assembly.

Although it is shown in FIG. 4 that lead wires are formed in the substrate of the IC using a multilevel interconnection technique, lead wires may be provided alternatively only on the upper and lower surfaces of the substrate which are connected through through-holes.

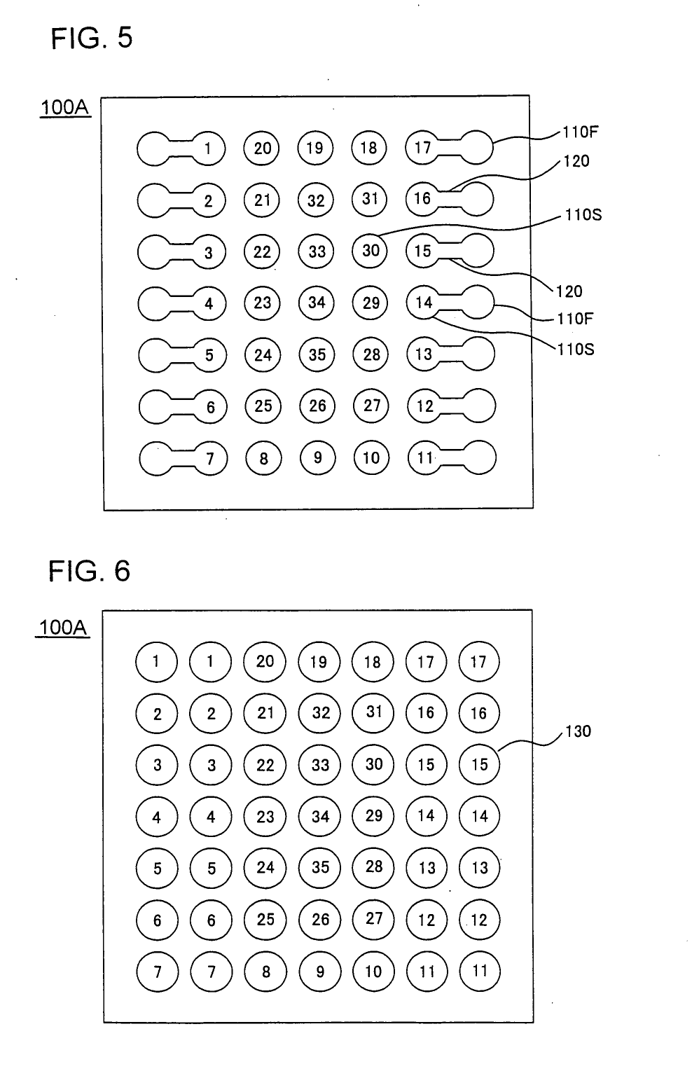

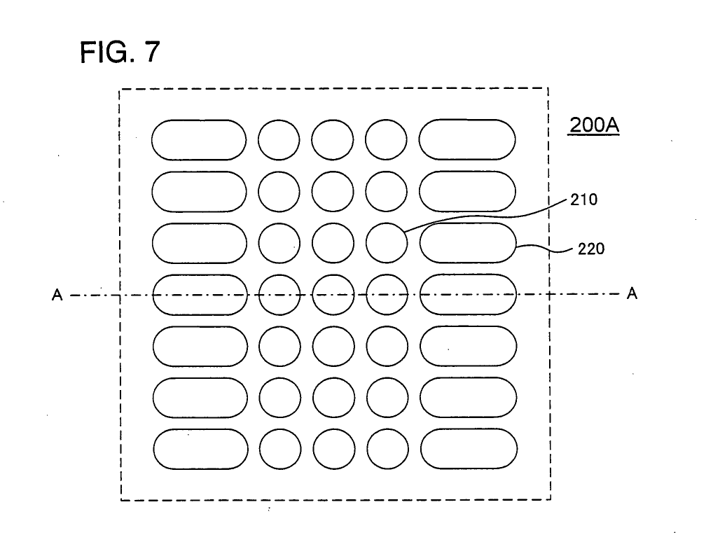

Referring to FIGS. 5-7, there is shown a second embodiment of the invention. More particularly, FIG. 5 shows a pattern of the pads arranged in a grid array configuration on one primary surface of an IC 100A according to the invention, and FIG. 6 shows a pattern of the bumps formed on the respective pads. FIG. 7 shows an arrangement or pattern of the electrodes formed on the assembly board for assembling the IC of FIGS. 5 and 6.

In the second example shown, the IC 100A is a grid array type IC which has a multiplicity of pads of substantially the same size arranged in a grid pattern configuration over a rectangular area and a multiplicity of bumps having substantially the same size and formed on the respective pads, as in the first embodiment.

As shown in FIG. 5, the IC 100A utilizes as the reinforcing pads 110F those pads located on a pair of opposing sides of the array. Each of the reinforcing pads 110F on the two sides is connected to the associated signal pad 110S that lies inside and adjacent the side by a straight linear inter-pad lead wires 120.

On the other hand, of the multiple pads 110 in the grid array configuration, pads other than those lying on the two sides are used as signal pads 110S to be connected to the internal circuits of the IC 10A. These signal pads 110S are numbered 1 through 35, as shown in FIG. 5.

Bumps 130 are formed on the respective pads 110, as shown in FIG. 6. Therefore, the bumps 130 have the same configuration as that of FIG. 2. The bumps 130 serving as terminals are numbered 1 through 35 in association with the corresponding signal pads 110S, as shown in FIG. 6. The bumps 130 formed on the reinforcing pads 110F are indicated by the same terminal numbers 1-7 and 11-17 as the associated signal pads 110S connected to the respective reinforcing pads 110F. Other features of the grid array configuration are the same as those of the first embodiment described above.

In the example shown in FIG. 7, the assembly board 200A is shown to have the same size as the IC 100A. In actuality, however, the assembly board 200A is larger than the IC 100A so that the assembly board can assemble further components and other ICs.

As shown in FIG. 7, the assembly board 200A is provided with patterned electrodes to be jointed to the bumps 130 of the IC 100A. These electrodes include side-wise electrodes 220 formed, as part of the circumferential electrodes, on two opposing sides of the array, and central electrodes 210 formed in the central region of the assembly board.

Each of the central electrodes 210 is bonded to an associated one of the bumps 130. Each of the central electrodes 210 is connected to a unique one of the reinforcing pads 110F numbered from 8 through 10 and from 18 through 35 by a bonding material.

Each of the side-wise electrodes 220 has an area that matches an associated side-wise reinforcing pad 110F and the signal pad 110S connected to the reinforcing pads 110F. Each of the side-wise electrodes 220 is connected to two bumps 130 en bloc by a bonding material, with one bump 130 formed on one side-wise reinforcing pad 110F and another bump formed on the adjacent signal pad 110S connected to the reinforcing pad 110F. No corner electrode is provided in the second embodiment shown.

A schematic sectional view of the second embodiment with the IC 100A assembled on the assembly board 200A, if taken along line A-A of FIG. 7, will be substantially the same as FIG. 4.

In the second embodiment, reinforcing pads 110F of the IC 100A are provided only on a pair of opposing sides of the array. ICs having reinforcing pads only on a pair of opposing sides in the manner as described above can prevent disconnection of bumps from the assembly board that can be otherwise induced by the deformation of the assembly board in a particular direction. This arrangement can be effectively applied to cases where the bumps in the grid array that are not used as external terminals are small in number. Other features of the second embodiment are the same as those of the first embodiment.

Although only solder has been used as the bonding material for the electrodes 220 and 230 in the examples shown above, bonding of the electrodes can be established by forming thereon bumps similar to the bumps 130 to be connected to the bumps 130.

1. An IC having a multiplicity of pads of substantially the same size and arranged in a grid array configuration, and a multiplicity of bumps of substantially the same size and respectively formed on said pads, wherein
said multiplicity of pads excluding the outermost ones of said array serve as signal pads to be connected with internal circuits of said IC;
said outermost pads serve as reinforcing pads to be connected to said signal pads inside and adjacent said outermost pads by inter-pad lead wires; and
said bumps are provided one for each of said signal pads and reinforcing pads.

2. The IC according to claim 1, wherein
said grid array configuration is generally rectangular;
three reinforcing pads located at each corner of the array (three reinforcing corner pads) are connected to one signal pad inside and adjacent said reinforcing corner pads (corner signal pad) by inter-pad lead wires, while each of the outermost reinforcing pads located on either side of said array but not at the corners (reinforcing side pads) is connected to an associated one of the signal pads inside and adjacent said side (inner side-wise signal pads) by an inter-pad lead wire.

3. The IC according to claim 2, wherein
said inter-pad lead wires connecting said three reinforcing corner pads at each corner to said corner signal pad have collectively a shape of X, while
said inter-pad lead wires connecting said reinforcing side pads to said inner side-wise signal pads have a linear shape.

4. An electronic apparatus comprising:
an IC having a multiplicity of pads of substantially the same size and arranged in a grid array configuration, and a multiplicity of bumps of substantially the same size and respectively formed on said pads, wherein
said multiplicity of pads excluding the outermost ones of said array serve as signal pads to be connected with internal circuits of said IC,
said outermost pads serve as reinforcing pads to be connected to signal pads inside and adjacent said outermost pads (inner side-wise signal pads) by inter-pad lead wires, and
said bumps are provided one for each of said signal pads and reinforcing pads; and
an assembly board having a multiplicity of circumferential electrodes each matching in size both at least one associated reinforcing pad and the signal pad connected to said reinforcing pad, and a multiplicity of central electrodes each matching in size an associated signal pad not connected to said reinforcing pad, wherein
each of said central electrodes is bonded to an associated one of said bumps, while each of said circumferential electrodes is bonded to a multiplicity of associated bumps en bloc.

5. The electronic apparatus according to claim 4, wherein at least one of said circumferential electrodes is omitted to provide a spacing for passing therethrough at least one lead-wire for a central electrode.

6. The electronic apparatus according to claim 4, wherein
said grid array configuration is generally rectangular;
three reinforcing pads located at each corner of the array (three reinforcing corner pads) are connected to one signal pad inside and adjacent said three reinforcing corner pads (corner signal pad) by inter-pad lead wires, while each of the outermost reinforcing pads located on either side of said array but not at the corners (reinforcing side pads) is connected to an associated one of the signal pads inside and adjacent said side (inner side-wise signal pad) by an inter-pad lead wire; and
said assembly board is provided with corner electrodes and side-wise electrodes, each corner electrode matching in size both said associated three reinforcing corner pads at that corner and the signal pad connected to said three reinforcing corner pads, and each side-wise electrode matching in size both an associated reinforcing side pad and said inner side-wise signal pad connected to said reinforcing side pad, wherein:
each of said central electrodes is individually bonded to an associated one of said bumps; while
each of said corner electrodes is bonded to four associated bumps en bloc; and
each of said side-wise electrodes is bonded to two associated bumps en bloc.

7. The electronic apparatus according to claim 6, wherein at least one of said side-wise electrodes is omitted to provide a spacing for passing therethrough at least one lead-wire for a central electrode.

8. The electronic apparatus according to claim 6, wherein
said inter-pad lead wires connecting said three reinforcing corner pads at each corner to said corner signal pad have collectively a shape of X, while said inter-pad lead wires connecting said reinforcing side pads to said associated inner side-wise signal pads have a linear shape.

9. The electronic apparatus according to claim 8, wherein at least one of said side-wise electrodes is omitted to provide a spacing for passing therethrough at least one lead-wire for a central electrode.

10. An IC having a multiplicity of pads of substantially the same size and arranged in a generally rectangular grid array configuration, and a multiplicity of bumps of substantially the same size and respectively formed on said pads, wherein:
said multiplicity of pads excluding the outermost pads in a pair of opposing sides of said rectangular array serve as signal pads to be connected to internal circuits of said IC; while
said outermost pads on said two opposing sides serve as reinforcing pads to be connected to the signal pads inside and adjacent said sides by linear inter-pad lead wires; and
said bumps are provided one for each of said signal pads and reinforcing pads.

11. An electronic apparatus, comprising:
an IC having a multiplicity of pads of substantially the same size and arranged in a generally rectangular grid array configuration, and a multiplicity of bumps of substantially the same size and respectively formed on said pads, wherein said multiplicity of pads excluding the outermost pads in a pair of opposing sides of said rectangular array serve as signal pads to be connected to internal circuits of said IC, while said outermost pads in said two opposing sides serve as reinforcing pads to be connected to the signal pads inside and adjacent said sides by linear inter-pad lead wires, and said bumps are provided one for each of said signal pads and reinforcing pads; and
an assembly board having a multiplicity of circumferential electrodes each matching in size both at least one associated reinforcing pad and the signal pad connected to said reinforcing pad, and a multiplicity of central electrodes each matching in size an associated signal pad not connected to said reinforcing pad, wherein
each of said central electrodes is bonded to an associated one of said bumps, while each of said circumferential electrodes is bonded to a multiplicity of associated bumps en bloc.

12. The electronic apparatus according to claim 11, wherein at least one of said circumferential electrodes is omitted to provide a spacing for passing therethrough at least one lead-wire for a central electrode.
